(19) United States
(12) Patent Application Publication
(10) Pub. No.: US 2026/0031128 A1
(43) Pub. Date: Jan. 29, 2026

(54) MEMORY AND ELECTRONIC DEVICE

(71) Applicant: CXMT Corporation, Hefei City (CN)

(72) Inventor: Zengquan WU, Hefei City (CN)

(73) Assignee: Changxin Memory Technology (Shanghai) Co., Ltd., Shanghai (CN)

(21) Appl. No.: 19/347,612

(22) Filed: Oct. 1, 2025

Related U.S. Application Data
(63) Continuation of application No. PCT/CN2024/085226, filed on Apr. 1, 2024.

(30) Foreign Application Priority Data
Apr. 6, 2023 (CN) 202310384290.3

(51) Int. Cl. G11C 11/406; G11C 11/4078

(52) U.S. Cl. CPC G11C 11/40611; G11C 11/40622; G11C 11/4078

(57) ABSTRACT

The present disclosure provides a memory and an electronic device. The memory includes a refresh indication circuit and a generation circuit. The refresh indication circuit decodes an external command signal indicating a directed refresh operation and outputs a first enable signal in an enabled state and a first block selection signal. The first enable signal is used to enable the generation circuit, such that the generation circuit outputs a target refresh command based on the first block selection signal.

### CROSS-REFERENCE TO RELATED APPLICATIONS

This is a continuation application of International Application No. PCT/CN2024/085226, filed on Apr. 1, 2024, which claims priority to Chinese Patent Application No. 202310384290.3, filed on Apr. 6, 2023. The disclosures of the above-referenced applications are hereby incorporated by reference in their entirety.

### BACKGROUND

Row hammer is a data attack method against the dynamic random access memory, which causes data loss in adjacent memory rows by frequently activating a certain memory row in a short period of time. In order to reduce the harm caused by the row hammer, a directed refresh management (directed refresh management, DRFM) function is introduced. The DRFM function means that: the memory performs a refresh operation on an address adjacent to a row address that has been accessed many times recently (that is, the number of activations of the row address is large), which is also referred to as a directed refresh operation.

### SUMMARY

The present disclosure relates to the field of semiconductor memories, and in particular to a memory and an electronic device.

In a first aspect, embodiments of the present disclosure provide a memory. The memory includes:
a refresh indication circuit, configured to receive an external command signal and output a first block selection signal and a first enable signal, where when the external command signal indicates a directed refresh operation, the first enable signal is in an enabled state and the first block selection signal indicates a first memory block selected to perform the directed refresh operation; and
a generation circuit, connected to the refresh indication circuit and configured to output N target refresh commands for the first memory block based on a bounded refresh configuration signal and the first block selection signal when the first enable signal is in an enabled state, where the bounded refresh configuration signal is used to specify the value of N.

In a second aspect, the embodiments of the present disclosure provide an electronic device. The electronic device includes the memory as described in the first aspect.

### BRIEF DESCRIPTION OF DRAWINGS

FIG. 1 is a schematic structural diagram of a memory provided according to an embodiment of the present disclosure;

FIG. 2 is a schematic diagram of the specific structure of a memory provided according to an embodiment of the present disclosure;

FIG. 3 is a schematic diagram of the specific structure of another memory provided according to an embodiment of the present disclosure;

FIG. 4 is a schematic structural diagram of a sampling control circuit provided according to an embodiment of the present disclosure;

FIG. 5 is a first schematic partial structural diagram of a sampling control circuit provided according to an embodiment of the present disclosure;

FIG. 6 is a second schematic partial structural diagram of a sampling control circuit provided according to an embodiment of the present disclosure;

FIG. 7 is a schematic partial structural diagram of a generation circuit provided according to an embodiment of the present disclosure; and

FIG. 8 is a schematic structural diagram of an electronic structure provided according to an embodiment of the present disclosure.

### DETAILED DESCRIPTION

The technical solutions in embodiments of the present disclosure will be clearly and completely described below with reference to the drawings in the embodiments of the present disclosure. It can be understood that the specific embodiments described herein are merely illustrative of a related application and are not intended to limit the application. In addition, it should be further noted that for the convenience of description, only the portions relevant to the related applications are shown in the drawings. Unless otherwise defined, all technical and scientific terms used herein have the same meaning as commonly understood by those skilled in the art to which the present disclosure pertains. The terms used herein are for the purpose of describing the embodiments of the present disclosure only and are not intended to limit the present disclosure. In the following description, reference is made to “some embodiments” which describe subsets of all possible embodiments, but it can be understood that “some embodiments” may be the same subset or different subsets of all possible embodiments, and may be combined with each other without conflict. It should be noted that the terms “first\second\third” referred to in the embodiments of the present disclosure are merely used for distinguishing similar objects and do not represent a specific ordering for the objects. It can be understood that “first\second\third” may be subjected to interchange of a specific order or sequence if permitted, such that the embodiments of the present disclosure described herein can be implemented in an order other than that shown or described.

The following are explanations of terms and corresponding relationships of partial terms involved in the embodiments of the present disclosure:
dynamic random access memory (dynamic random access memory, DRAM);
synchronous dynamic random access memory (synchronous dynamic random access memory, SDRAM);
double data rate SDRAM (double data rate SDRAM, DDR);
low power DDR (low power DDR, LPDDR);
5th LPDDR (5th LPDDR, LPDDR5);
mode register (mode register, MR);
bounded refresh configuration (bounded refresh configuration, BRC); and
system on chip (system on chip, SoC).

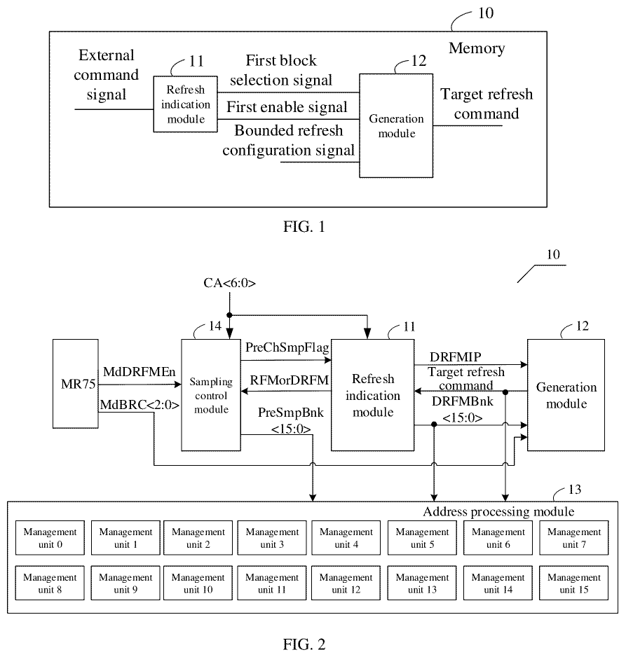

The embodiments of the present disclosure are described in detail below with reference to the drawings. In one embodiment of the present disclosure, referring to FIG. 1, a schematic structural diagram of a memory 10 provided according to an embodiment of the present disclosure is shown. As shown in FIG. 1, the memory 10 includes:
a refresh indication circuit 11, configured to receive an external command signal and output a first block selection signal and a first enable signal, where when the external command signal indicates a directed refresh operation, the first enable signal is in an enabled state and the first block selection signal indicates a first memory block selected to perform the directed refresh operation; and
a generation circuit 12, connected to the refresh indication circuit 11 and configured to output N target refresh commands for the first memory block based on a bounded refresh configuration signal and the first block selection signal when the first enable signal is in an enabled state, where the bounded refresh configuration signal is used to specify the value of N.

It should be understood that in the embodiments of the present disclosure, the memory block refers to a bank and is also referred to as a memory bank.

It should be noted that the memory 10 may be various types of dynamic memories 10 (for example, DRAM, SDRAM, DDR, and LPDDR), and the embodiments of the present disclosure are only illustrated with LPDDR5 as an example but do not constitute a specific limitation.

It should be noted that the external command signal is transmitted to the memory 10 by a memory controller or SoC, and specifically includes a clock signal, a command address signal CA<6:0>, and a chip select signal CS. When the chip select signal CS indicates that the memory 10 is selected, the memory 10 samples and decodes the command address signal CA<6:0> according to the clock signal to know which operation it is indicated to perform. The operation types of the memory include at least: pre-charging, regular refresh, directed refresh, reading, writing, activation, or the like.

The directed refresh operation essentially refers to a refresh for a memory row adjacent to the target memory row, and the bounded refresh configuration (BRC) signal is specifically used to indicate the range of the “adjacent memory row”, which may be set by the user/system. Illustratively, a parameter setting method for LPDDR5 is provided. As shown in FIG. 2, the bounded refresh configuration signal may be represented as MdBRC<2:0>, which is specifically given by a mode register MR75. MR75 OP[0] indicates whether a BRC function is supported; MR75 OP[5:4] further indicates the mode of the BRC (i.e., determines a refresh for a few rows adjacent to the target memory row based on the value of the BRC), and MR75 OP[0] and MR75 OP[5:4] collectively form MdBRC<2:0>.

It should be further noted that each target refresh command includes a refresh enable signal (embodied as a pulse) and the address of a target refresh memory block, and the generation circuit 12 outputs a total of N target refresh commands generated in sequence. In addition, in FIG. 2, the first enable signal is represented as DRFMIP and the first block selection signal is represented as DRFMBnk<15:0>.

As can be seen from the above, the memory 10 implements the DRFM function through the refresh indication circuit 11 and the generation circuit 12, such that the memory 10 can perform refresh processing on a row adjacent to the target memory row that has been activated many times recently, thereby reducing the occurrence probability of a row hammer event and improving data correctness.

In some embodiments, as shown in FIG. 2, the memory 10 further includes an address processing circuit 13. The address processing circuit 13 stores the activation information of each memory block. The address processing circuit 13 is connected to the generation circuit 12, and is configured to receive the target refresh command, perform a second verification on a memory block corresponding to the target refresh command based on the activation information of each memory block, and confirm the second verification as successful if the memory block corresponding to the target refresh command has been activated in the previous period of time; otherwise, confirm the second verification as failed and perform a preset handling operation if the memory block corresponding to the target refresh command has not been activated in the previous period of time.

It should be noted that the preset handling operation at least includes the blocking of the N target refresh commands. It should be understood that the target refresh command is generally embodied in the form of a pulse, and thus the preset handling operation may specifically be the blocking of the corresponding pulse.

As can be inferred from the DRFM mechanism, the memory row corresponding to the target refresh command should be a memory row that may be subject to the row hammer. If the memory block corresponding to the target refresh command has not been activated in the previous period of time, it means that the memory row in the memory block may not be subjected to the row hammer, which means that the address processing circuit 13 has received an erroneous instruction, so the target refresh command will not be executed. In particular, the expression form of the activation information of the memory block may be embodied as various contents, as long as it can express that the memory block has been activated, which is detailed in the following description.

As such, since the address processing circuit 13 may perform the second verification on the target refresh command, an erroneous directed refresh operation can be prevented from being performed.

In some embodiments, the address processing circuit 13 is further configured to, after the second verification succeeds, determine a target memory row in the memory block corresponding to the target refresh command and perform refresh processing on N rows adjacent to the target memory row by using the N target refresh commands.

It should be noted that, in one case, the target memory row is specified by the external command signal (specifically, CA<6:0>), that is, the target memory row is specified by the memory controller or SoC. In another case, the target memory row is selected by the memory 10 according to the activation status of each memory row in the last period of time.

However, no matter how the target memory row is determined, the target memory row refers to a memory row whose number of activation in the previous period of time meets a preset condition. The preset condition may be, but is not limited to, one or a combination of the following: (1) the number of activation in the previous period of time is the largest; (2) the memory row whose number of activation in the previous period of time is larger than the threshold value is randomly selected; (3) the memory row is the most recently activated; and (4) the memory row whose number of activation is the largest among B memory rows activated recently. The time length of the “previous period of time” and the value of B may both be set according to practical application scenarios.

In some embodiments, as shown in FIG. 2, the refresh indication circuit 11 is further configured to receive the target refresh command, perform a first verification on the target refresh command based on the first block selection signal DRFMBnk<15:0>, output a verification result signal, and transmit the verification result signal to the address processing circuit 13. If a memory block corresponding to the first block selection signal DRFMBnk<15:0> is consistent with the memory block corresponding to the target refresh command, the verification result signal characterizes that the first verification succeeds; if the memory block corresponding to the first block selection signal DRFMBnk<15:0> is inconsistent with the memory block corresponding to the target refresh command, the verification result signal characterizes that the first verification fails.

The address processing circuit 13 is further configured to receive the verification result signal and, if the verification result signal characterizes that the first verification fails, perform the aforementioned preset handling operation (for example, the blocking of the target refresh command) and no longer perform the aforementioned second verification; or, if the verification result signal characterizes that the first verification succeeds, continue to perform the aforementioned second verification.

As such, after the generation circuit 12 outputs the target refresh command, the refresh indication circuit 11 performs the first verification on the operation object of the target refresh command. If the first verification fails, the address processing circuit 13 directly blocks the received target refresh command without performing the second verification; if the first verification succeeds, the address processing circuit 13 continues to perform the second verification on the operation object of the target refresh command, and the corresponding refresh processing is performed only when the second verification succeeds, thereby preventing an erroneous operation from being performed.

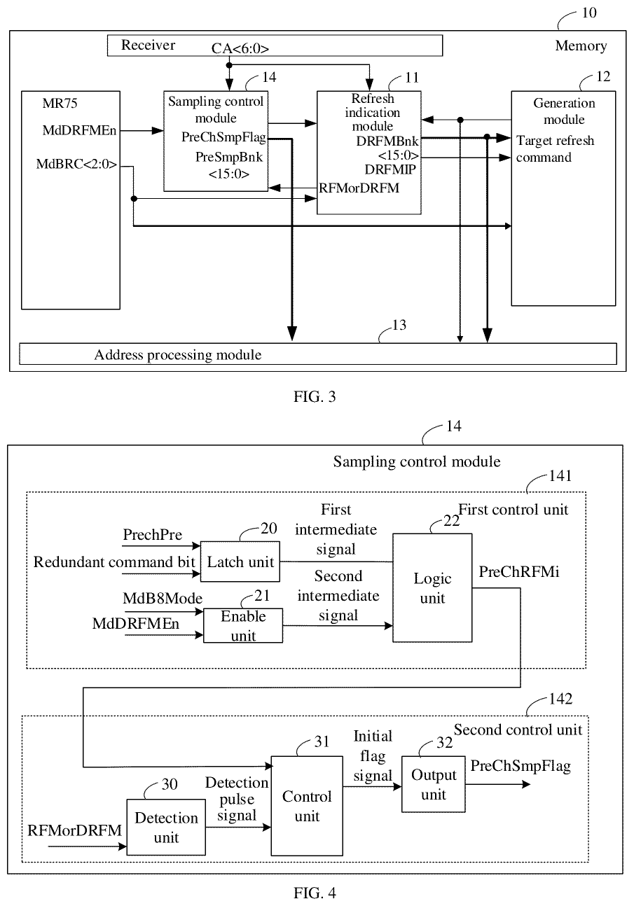

Based on this, in other embodiments, as shown in FIG. 3, the refresh indication circuit 11 is further configured to receive a bounded refresh configuration signal MdBRC<2:0>, perform a third verification on the number of target refresh commands based on the bounded refresh configuration signal MdBRC<2:0>, and confirm the third verification to be successful if the number indicated by the bounded refresh configuration signal MdBRC<2:0> is consistent with the number of target refresh commands; and confirm the third verification to be failed if the number indicated by the bounded refresh configuration signal MdBRC<2:0> is inconsistent with the number of target refresh commands.

Correspondingly, the refresh indication circuit 11 is further configured to generate a verification result signal based on the results of the first verification and the third verification, and transmit the verification result signal to the address processing circuit 13.

The address processing circuit 13 is further configured to receive the verification result signal and, if the verification result signal characterizes that the first verification or the third verification fails, perform the aforementioned preset handling operation and no longer perform the second verification; or, if the verification result signal characterizes that the first verification and the third verification both succeed, continue to perform the steps of the second verification.

In a specific embodiment, the refresh indication circuit 11 may first perform the first verification for the operation object, and then perform the third verification for the number on the basis of the success of the first verification. If the first verification fails, the third verification does not need to be performed, thereby improving the verification efficiency.

As such, after the generation circuit 12 outputs the target refresh command, the refresh indication circuit 11 performs the verification for the operation object (the first verification) and the verification for the number (the third verification) on the target refresh command at the same time. After the first verification and the third verification both succeed, the target refresh command is transmitted to the address processing circuit 13. The address processing circuit 13 performs the second verification on the operation object of the target refresh command again, and the corresponding refresh processing is performed only when the second verification succeeds, such that an erroneous operation can be better prevented from being performed.

In some embodiments, as shown in FIG. 2 or 3, the memory 10 further includes:
a sampling control circuit 14, configured to receive the external command signal CA<6:0>, and output a second block selection signal PreSmpBnk<15:0> if the external command signal CA<6:0> indicates the execution of a pre-charging operation, where the second block selection signal PreSmpBnk<15:0> indicates a second memory block selected to perform the pre-charging operation; and
the address processing circuit 13, connected to the sampling control circuit 14 and further configured to receive the second block selection signal PreSmpBnk<15:0> and store the activation information of the second memory block based on the second block selection signal PreSmpBnk<15:0>.

It should be noted that the first memory block and the second memory block are only memory blocks selected for distinguishing different signals, and do not refer to a specific memory block. In short, the first memory block may be any memory block and the second memory block may also be any memory block.

In particular, during the row hammer, data errors in adjacent rows are caused by repeated pre-charging and activation operations, and thus the information that a memory block is pre-charged may be recorded as activation information.

As such, each time the memory 10 is indicated to perform a pre-charging operation, the address processing circuit 13 will store the activation information of the second memory block for subsequent use.

It should be noted that the address processing circuit 13 includes a management unit. The management unit is configured to obtain and store the activation information of the second memory block. Here, there are many possibilities for the arrangement details of the management unit and the specific meanings of the activation information of the memory block, and the following provides several examples:

In possibility one, for M memory blocks, only 1 management unit is arranged, and the management unit records each pre-charged memory block in the last period of time and its respective number of pre-charging; that is, the activation information of the memory block refers to the address of the pre-charged memory block and the number of pre-charging thereof.

In possibility two, for M memory blocks, only 1 management unit is arranged, and the management unit only records each pre-charged memory block in the last period of time; that is, the activation information of the memory block refers to the address of the pre-charged memory block.

In possibility three, for M memory blocks, only 1 management unit is arranged, and the management unit records each pre-charged memory block and the activated gating row address in the last period of time (the memory block to which the gating row address belongs cannot be distinguished); that is, the activation information of the memory block refers to the address of the pre-charged memory block and the activated gating row address.

In possibility four, for M memory blocks, M management units are arranged, where the management units are in one-to-one correspondence with the memory blocks, and each management unit records the activated gating row address in the corresponding memory block in the last period of time and the number of activation thereof; that is, the activation information of the memory block refers to the activated gating row address and the number of activation thereof; in particular, since the management units are in one-to-one correspondence with the memory blocks, the address of the pre-charged memory block and the number of pre-charging thereof can also be known.

In possibility five, for M memory blocks, M management units are arranged, where the management units are in one-to-one correspondence with the memory blocks, and each management unit records the number of pre-charging and the activated gating row address of the corresponding memory block in the last period of time (that is, the memory block to which the gating row address belongs can be recorded); that is, the activation information of the memory block refers to the address of the pre-charged memory block, the number of pre-charging thereof, and the activated gating row address.

In particular, in possibility one and possibility two, since the management unit does not record the gating row address, the object of the directed refresh operation be specified by the external command signal; in possibility three to possibility five, the object of the directed refresh operation may be determined by the memory itself from the recorded gating row address.

Take the aforementioned possibility four as an example, a specific embodiment is provided. Correspondingly, as shown in FIG. 2, the address processing circuit 13 includes M management units (FIG. 2 shows an example where M=16), that is, each management unit is configured to manage one memory block. The i-th management unit is configured, after the second block selection signal PreSmpBnk<15:0> is received, to perform sampling and latch processing on a gating row address (externally input) based on the second block selection signal PreSmpBnk<15:0> if the second block selection signal PreSmpBnk<15:0> indicates that the i-th memory block is selected to perform the pre-charging operation, where the gating row address indicates a memory row selected to perform an activation operation; and after the address processing circuit 13 confirms the second verification as successful, to determine the target memory row according to at least one latched gating row address. Both i and M are positive integers, and i≤M.

The specific process of the aforementioned “the address processing circuit 13 performs a verification on the target refresh command” is as follows: the address processing circuit 13 is configured to perform the aforementioned second verification according to whether the management unit of the memory block corresponding to the first block selection signal DRFMBnk<15:0> latches the gating row address. Specifically, the j-th management unit is further configured, after the first block selection signal DRFMBnk<15:0> is received, to perform verification processing according to whether the j-th management unit itself latches the gating row address, assuming that the first block selection signal DRFMBnk<15:0> indicates that the j-th memory block is selected to perform the directed refresh operation. If the j-th management unit latches at least one gating row address, the second verification is confirmed to be successful; if the j-th management unit does not latch any gating row address, the second verification is confirmed as failed.

It should be noted that the management unit may be implemented through an address register and a counter.

In some embodiments, as shown in FIG. 2 or 3, the sampling control circuit 14 is configured to decode the external command signal CA<6:0>, and generate a pre-charge command signal PreChSmpFlag in an enabled state and the second block selection signal PreSmpBnk<15:0> if the external command signal CA<6:0> characterizes the pre-charging operation.

The refresh indication circuit 11 is further configured to receive the pre-charge command signal PreChSmpFlag and enter an enabled state based on the pre-charge command signal in an enabled state.

It should be noted that when any external command signal CA<6:0> indicates the pre-charging operation, the sampling control circuit 14 outputs the second block selection signal PreSmpBnk<15:0>, such that the address processing circuit 13 performs latch processing on the activation information of the corresponding memory block while the refresh indication circuit 11 is enabled.

In other embodiments, the refresh indication circuit 11 is further configured to decode the external command signal CA<6:0> and output a feedback signal RFMorDRFM, where if the feedback signal RFMorDRFM indicates the directed refresh operation, the feedback signal RFMorDRFM has a pulse; if the feedback signal RFMorDRFM does not indicate the directed refresh operation, the feedback signal RFMorDRFM keeps the level state unchanged.

The sampling control circuit 14, connected to the refresh indication circuit 11, is further configured to receive the feedback signal RFMorDRFM and adjust the pre-charge command signal PreChSmpFlag to be in a sleep state based on the pulse transition edge of the feedback signal RFMorDRFM.

Here, the pulse transition edge may be a rising edge or a falling edge, depending on the specific generation method of the pulse.

It should be noted that, during the operation cycle of the memory 10, the memory 10 will continuously receive external command signals CA<6:0> to perform different operations respectively. Starting from the memory 10 being indicated to perform the pre-charging operation, the sampling control circuit 14 adjusts the pre-charge command signal PreChSmpFlag to be in an enabled state, the address processing circuit 13 latches corresponding activation information according to the second block selection signal PreSmpBnk<15:0> (the sub-signal of the second block selection signal PreSmpBnk<15:0> may be used as an enable signal to trigger the latch operation after an OR operation), and the refresh indication circuit 11 is enabled; after the memory 10 is indicated to perform the directed refresh operation, the pre-charge command signal PreChSmpFlag is adjusted to be in a sleep state by using the pulse transition edge of the feedback signal RFMorDRFM output by the refresh indication circuit 11, and the refresh indication circuit 11 is no longer enabled.

Note that the pre-charge command signal PreChSmpFlag in an enabled state can enable the refresh indication circuit 11, but the disabling mechanism of the refresh indication circuit 11 has the following possibilities:

In possibility one, the refresh indication circuit 11 is further configured to receive a disabling control signal and enter a disabled state based on the disabling control signal. That is, the pre-charge command signal PreChSmpFlag in a sleep state does not cause the refresh indication circuit 11 to be disabled, and the disabling of the refresh indication circuit 11 is controlled by other signals, such that the refresh indication circuit 11 can complete operations such as the first verification/the third verification.

In possibility two, the pre-charge command signal PreChSmpFlag in a sleep state will control the refresh indication circuit 11 to enter a disabled state. Correspondingly, after the external command signal CA<6:0> indicating the directed refresh operation is received, the refresh indication circuit 11 will delay transmitting the feedback signal RFMorDRFM, such that the refresh indication circuit 11 can complete operations such as the first verification/the third verification.

In possibility three, the pre-charge command signal PreChSmpFlag in a sleep state will control the refresh indication circuit 11 to enter a disabled state. Correspondingly, the feedback signal RFMorDRFM is generated and transmitted only after the external command signal CA<6:0> indicating the directed refresh operation is received and the refresh indication circuit 11 transmits a verification result signal (proving the end of the first verification/the third verification).

For the above possibility one, a specific embodiment is provided. The generation circuit 12 is further configured to generate a disabling control signal; and control the disabling control signal to generate one pulse after the N target refresh commands are output (i.e., after delaying for a period of time).

The refresh indication circuit is further configured to receive the disabling control signal and enter a disabled state based on the pulse transition edge of the disabling control signal, such that the refresh indication circuit 11 does not need to operate in a subsequent process of the directed refresh operation, thereby helping to save energy.

In the above description, the “enabled state” and the “sleep state” of a certain signal are distinguished through logic levels, and at the same time, the logic level rules for the “enabled state”/“sleep state” of different signals may be different and need to be selected according to practical application scenarios. For example, if the signal is at a high level, it is in an enabled state; if the signal is at a low level, it is in a sleep state. For another example, if the signal is at a low level, it is in an enabled state; if the signal is at a high level, the signal is in a sleep state.

Illustratively, the specific structure of the sampling control circuit 14 is provided below. As shown in FIG. 4, the sampling control circuit 14 includes:
a first control unit 141, configured to receive and decode the external command signal CA<6:0>, where if the decoded result characterizes a pre-charge command, a pre-charge signal PrechPre is in an enabled state; if the pre-charge signal PrechPre is in an enabled state and the redundant command bits of the external command signal are at a preset level, an intermediate control signal PreChRFMi in an enabled state is output; if the pre-charge signal PrechPre is in a sleep state or the redundant command bits are not at the preset level, the intermediate control signal PreChRFMi in a sleep state is output; and
a second control unit 142, connected to the first control unit and configured to output the pre-charge command signal PreChSmpFlag in an enabled state when the intermediate control signal PreChRFMi in the enabled state is received and adjust the pre-charge command signal PreChSmpFlag to be in a sleep state after the feedback signal RFMorDRFM is received.

It should be noted that the redundant command bits refer to other command bits that can be freely set by the manufacturer to identify a corresponding command, in addition to the command bits specified by the Joint Electron Device Engineering Council (JEDEC), among the command bits characterizing a certain command.

In a specific embodiment, as shown in FIG. 4, the first control unit 141 includes:
a latch unit 20, configured to latch the redundant command bits based on the pre-charge signal PrechPre and output a first intermediate signal, where, when the pre-charge signal PrechPre is in an enabled state and the redundant command bits are at the preset level, the first intermediate signal is in a first preset state;
an enable unit 21, configured to receive a mode signal MdB8Mode and a directed refresh enable signal MdDRFMEn and output a second intermediate signal, where the second intermediate signal is in an enabled state only when the mode signal MdB8Mode is in a sleep state and the directed refresh enable signal MdDRFMEn is in an enabled state; the mode signal MdB8Mode in an enabled state characterizes that the memory 10 does not support a directed refresh function, and the directed refresh enable signal MdDRFMEn in an enabled state characterizes that the directed refresh function is enabled; and
a logic unit 22, configured to receive the first intermediate signal and the second intermediate signal and output the intermediate control signal PreChRFMi in an enabled state only when the first intermediate signal is in the first preset state and the second intermediate signal is in an enabled state.

In particular, when the mode signal MdB8Mode is in an enabled state, the memory 10 enters a B8 mode, and the B8 mode does not support the directed refresh operation.

That is, in the embodiments of the present disclosure, it is necessary not only for the external command signal CA<6:0> to characterize a pre-charge instruction, but also for the redundant command bits of CA<6:0> to be at the preset level, such that the first intermediate signal in the first preset state can be obtained, thereby satisfying the customization requirement. Here, according to practical application scenarios, the first intermediate signal may refer to a single signal or a plurality of signals. If the first intermediate signal refers to a plurality of signals, “the first intermediate signal being in the first preset state” means that the sub-signal at each bit needs to be in a respective preset state.

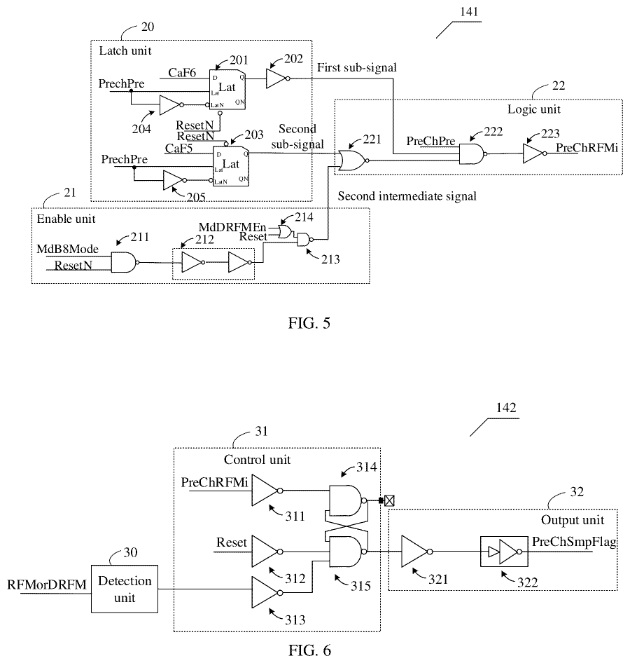

In a specific embodiment, the following scenario settings are provided: The redundant command bits include a first command bit Ca6 and a second command bit Ca5; in particular, the “redundant command bits being at the preset level” means that both the second sampling result CaF6 of the first command bit Ca6 at the falling edge of the clock signal and the first sampling result CaF5 of the second command bit Ca5 at the falling edge of the clock signal are at a low level, and the pre-charge signal PrechPre is high, that is, the signal is in an enabled state. Correspondingly, as shown in FIG. 5, a first latch unit 20 includes a first latch 201 and a first inverter 202, and a second latch unit 20 includes a second latch 203. The clock terminal (Lat) of the first latch 201 receives the pre-charge signal PrechPre, the inverted clock terminal (LatN) of the first latch 201 receives the inversion signal of the pre-charge signal PrechPre, the input terminal (D) of the first latch 201 receives the second sampling result CaF6 of the first command bit at the falling edge of the clock signal, the non-inverting output terminal (Q) of the first latch 201 is connected to the input terminal of the first inverter 202, and the output terminal of the first inverter 202 outputs a first sub-signal. The clock terminal (Lat) of the second latch 203 receives the pre-charge signal PrechPre, the inverted clock terminal (LatN) of the second latch 203 receives the inversion signal of the pre-charge signal PrechPre, the input terminal (D) of the second latch 203 receives the sampling result CaF5 of the second command bit at the falling edge of the clock signal, and the output terminal (Q) of the second latch 203 outputs a second sub-signal. In addition, as shown in FIG. 5, the latch unit 20 further includes a NOT gate 204 and a NOT gate 205, both of which are configured to obtain the inversion signal of the pre-charge signal PrechPre.

It should be noted that the first sub-signal and the second sub-signal collectively form the first intermediate signal, and “the first intermediate signal being in the first preset state” means that the first sub-signal is at a high level and the second sub-signal is at a low level.

It should be noted that the operating principle of the first latch 201/the second latch 203 is as follows: When the clock terminal (Lat) is at a high level, the signal of the input terminal (D) is transmitted to the output terminal (Q); when the clock terminal (Lat) is at a low level, the signal of the input terminal (D) is prevented from being transmitted to the output terminal (Q), and the output terminal (Q) continues to be in the previous state. In addition, the level states of the inverted output terminal (QN) and the input terminal (D) are opposite. In addition, both the first latch 201 and the second latch 203 are reset at a low level, and the reset terminals of the first latch 201 and the second latch 203 receive a system reset inversion signal ResetN. Illustratively, when the system reset signal Reset is at a high level (while the system reset inversion signal ResetN is at a low level), the memory 10 performs reset processing. That is, when the system is reset, the first sub-signal is at a low level and the second sub-signal is at a high level.

As such, when the external command signal CA<6:0> is decoded to generate the pre-charge signal PrechPre at a high level and both CAF6 and CAF5 are at a low level, the first sub-signal is at a high level and the second sub-signal is at a low level.

In a specific embodiment, the following scenario settings are provided: The enabled state of the directed refresh enable signal MdDRFMEn (which is specifically given by a mode register (MR75 OP[2]), with reference to Table 5) refers to a high level; the enabled state of the mode signal MdB8Mode refers to a high level, the level states of the system reset inversion signal ResetN and the system reset signal Reset are opposite, the system reset signal Reset at a high level indicates a reset operation, and the enabled state of the second intermediate signal refers to a low level. Correspondingly, as shown in FIG. 5, the enable unit 21 includes a first NAND gate 211, a first buffer 212, a second NAND gate 213, and a first OR gate 214. The two input terminals of the first NAND gate 211 respectively receive the mode signal MdB8Mode and the system reset inversion signal ResetN. The output terminal of the first NAND gate 211 is connected to the input terminal of the first buffer 212. The two input terminals of the first OR gate 214 respectively receive the directed refresh enable signal MdDRFMEn and the system reset signal Reset. The two output terminals of the second NAND gate 213 are respectively connected to the output terminal of the first NAND gate 211 and the output terminal of the first buffer 212. The output terminal of the second NAND gate 213 outputs the second intermediate signal.

As such, the second intermediate signal is at a low level only when the mode signal MdB8Mode is at a low level and the directed refresh enable signal MdDRFMEn is at a high level.

In a specific embodiment, as shown in FIG. 5, the logic unit 22 includes a first NOR gate 221, a third NAND gate 222, and a second NOT gate 223. The two input terminals of the first NOR gate 221 respectively receive the second sub-signal and the second intermediate signal. The output terminal of the first NOR gate 221 outputs a fourth intermediate signal. The three input terminals of the third NAND gate 222 respectively receive the pre-charge signal PrechPre, the first sub-signal, and the output signal of the first NOR gate 221. The output terminal of the third NAND gate 222 is connected to the input terminal of the second NOT gate 223. The output terminal of the second NOT gate 223 shows the intermediate control signal PreChRFMi.

That is, the logic unit 22 will also receive the pre-charge signal PrechPre to prevent subsequent signals from floating.

As such, when the second sub-signal is at a low level, the second intermediate signal is at a low level, the first sub-signal is at a high level, and the pre-charge signal PrechPre is at a high level, the intermediate control signal PreChRFMi is at a high level; that is, the enabled state of the intermediate control signal PreChRFMi is at a high level.

In some embodiments, as shown in FIG. 4, the second control unit 142 includes:
a detection unit 30, configured to receive the feedback signal RFMorDRFM and output a detection pulse signal, where, each time the pulse transition edge of the feedback signal RFMorDRFM is detected, one pulse is generated by the detection pulse signal;
a control unit 31, connected to the detection unit 30 and configured to receive the intermediate control signal PreChRFMi and the detection pulse signal, perform latch processing based on the intermediate control signal PreChRFMi and the detection pulse signal, and generate an initial flag signal; and
an output unit 32, connected to the control unit 20 and configured to perform inverted processing on the initial flag signal and output the pre-charge command signal PreChSmpFlag.

Here, the pulse transition edge refers to a rising edge or a falling edge. However, in the same embodiment, the pulse transition edge of the same signal cannot be both a rising edge and a falling edge.

In some embodiments, in a scenario where a pulse generated by the detection pulse signal is a positive pulse, as shown in FIG. 6, the control unit 31 includes a third NOT gate 311, a fourth NOT gate 312, a fifth NOT gate 313, a fourth NAND gate 314, and a fifth NAND gate 315. The input terminal of the third NOT gate 311 receives the intermediate control signal PreChRFMi. The input terminal of the fourth NOT gate 312 receives the system reset signal Reset. The input terminal of the fifth NOT gate 313 receives the detection pulse signal. The two input terminals of the fourth NAND gate 314 are respectively connected to the output terminal of the third NOT gate 311 and the output terminal of the fifth NAND gate 315. The three input terminals of the fifth NAND gate 315 are respectively connected to the output terminal of the fourth NOT gate 312, the output terminal of the fifth NOT gate 313, and the output terminal of the fourth NAND gate 314. The output terminal of the fifth NAND gate 315 outputs the initial flag signal.

It should be noted that (1) the system reset signal Reset has a positive pulse in the initialization stage, such that the initial flag signal=1; (2) when the intermediate control signal PreChRFMi=0 (is in a sleep state), since Reset=0 and the detection pulse signal=1, the initial flag signal=1 (continues to be in the previous state); (3) when the intermediate control signal PreChRFMi=1 (is in an enabled state), since Reset=0 and the detection pulse signal=0, the initial flag signal=0, and if the intermediate control signal PreChRFMi=0 during this period, the initial flag signal=0; (4) when the detection pulse signal=1 (when there is an edge transition in the detection pulse signal), the initial flag signal=1, so as to conform to the previous signal change logic. In particular, the initial flag signal is inverted to obtain the pre-charge command signal PreChSmpFlag, and the enabled state of the pre-charge command signal PreChSmpFlag refers to a high level.

Correspondingly, the output unit 32 includes a sixth NOT gate 321 and a second buffer 322. The input terminal of the sixth NOT gate receives the initial flag signal. The output terminal of the sixth NOT gate is connected to the input terminal of the second buffer. The output terminal of the second buffer outputs the pre-charge command signal PreChSmpFlag.

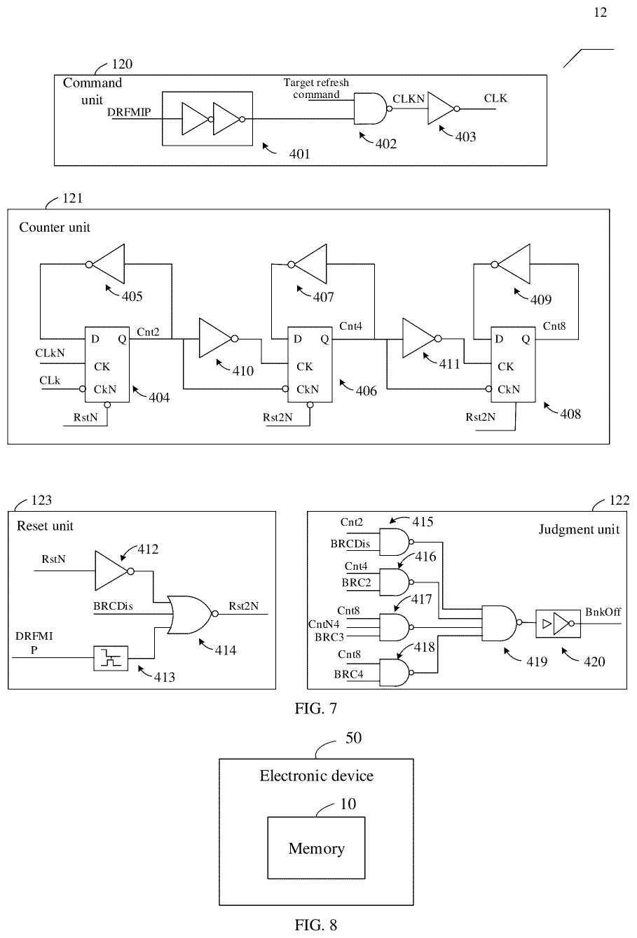

In a specific embodiment, as shown in FIG. 7, the generation circuit 12 includes:
a command unit 120, configured to receive the first enable signal DRFMIP and the target refresh command, output a count clock signal based on the target refresh command when the first enable signal DRFMIP is in an enabled state, and control the level state of the count clock signal to keep unchanged when the first enable signal is in a sleep state;
a counter unit 121, configured to receive the count clock signal, perform counting based on the count clock signal, and generate a command count value; and
a judgment unit 122, configured to compare the command count value with N and generate the disabling control signal based on the comparison result, where if the command count value reaches N, the disabling control signal is controlled to generate one pulse; if the command count value is less than N, the disabling control signal is controlled to keep the level state unchanged.

As such, during the period when the first enable signal is in an enabled state, the counter unit 121 will actually perform counting on the target refresh command (embodied as a pulse), thereby generating the command count value. The command count value reaches N, indicating that N target refresh commands have been generated; the determination circuit 122 will control the disabling control signal to generate one pulse, so as to turn off the refresh indication circuit 11 subsequently.

In some embodiments, the judgment unit 122 is configured to control the disabling control signal to generate a rising edge when the command count value reaches N; and control the disabling control signal to generate a falling edge after the command count value continues to increase. The falling edge of the disabling control signal is used to control the disabling of the refresh indication circuit 11.

As such, when the command count value reaches N, the disabling control signal generates a rising edge; after a certain time, the disabling control signal generates a falling edge and the falling edge is used to control the disabling of the refresh indication circuit 11, thereby reserving time for the refresh indication circuit 11 to perform verification.

In a specific embodiment, the judgment unit 122 is configured to control the disabling control signal to generate a falling edge when the command count value reaches N+M. Here, M is an arbitrary natural number, depending on actual circuit accuracy. At the same time, the value of M may be different for different bounded refresh configurations.

In a specific embodiment, the enabled state of the first enable signal DRFMIP refers to a high level. As shown in FIG. 7, the command unit 120 includes a second buffer 401, a fourth NAND gate 402, and a third NOT gate 403; that is, the command unit 120 performs an AND operation on the first enable signal DRFMIP and the target refresh command, so as to obtain the count clock signal CLK.

The counter unit 121 includes three count units which are cascaded. The first-stage count unit includes a first flip-flop 404 and a fourth NOT gate 405, the second-stage count unit includes a second flip-flop 406 and a fifth NOT gate 407, and the third-stage count unit includes a third flip-flop 408 and a sixth NOT gate 409. The count clock signal CLK enters from the positive clock terminal (CK) of the first flip-flop 404, and the inversion signal CLK of the count clock signal enters from the negative clock terminal (CKN) of the first flip-flop 404. At the same time, the counter 121 further includes a seventh NOT gate 410 and an eighth NOT gate 411, so as to ensure that the second-stage count unit and the third-stage count unit can receive signals conforming to the specification. In particular, the first-stage count unit outputs a count sub-signal Cnt2, the second-stage count unit outputs a count sub-signal Cnt4, and the third-stage count unit outputs a count sub-signal Cnt8; Cnt2, Cnt4, and Cnt8 collectively form the command count value.

Illustratively, the pulse generated by the disabling control signal Bankoff is a positive pulse whose falling edge causes the refresh indication circuit 11 to be disabled. The judgment unit 122 includes a fifth NAND gate 415, a sixth NAND gate 416, a seventh NAND gate 417, an eighth NAND gate 418, a ninth NAND gate 419, and a third buffer 419. When the aforementioned OP[0]=0, characterizing that a BRC mode is not supported, BRCdis=1, only one refresh operation is performed in this case, and N=1; when OP[5:4]=00, BRC2=1, characterizing±1 rows of the target memory row to be refreshed and N=2; when OP[5:4]=01, BRC3=1, characterizing+2 rows of the target memory row to be refreshed and N=4; when OP[5:4]=10, BRC4=1, characterizing+3 rows of the target memory row to be refreshed and N=6.

Specifically, if BRCDis=1 and BRC2=BRC3=BRC4=0, the value of N is 1 in this case. After one target refresh command is generated, Cnt2=1, Cnt4=Cnt8=0, and the disabling control signal Bankoff jumps to be at a high level, and after two target refresh commands are generated, Cnt2=0, Cnt4=1, Cnt8=1, and the disabling control signal Bankoff jumps to be at a low level; that is, after the two target refresh commands, the disabling control signal Bankoff generates a falling edge, so as to turn off the refresh indication circuit 11. It should be noted that the refresh indication circuit 11 is turned off when the 2nd target refresh command is generated so as to reserve time for the refresh indication circuit 11 to perform the verification operation.

If BRC2=1 and BRCDis=BRC3=BRC4=0, the value of N is 2 in this case. After two target refresh commands are generated, Cnt2=0, Cnt4=1, Cnt8=0, and the disabling control signal Bankoff jumps to be at a high level, and after four target refresh commands are generated, Cnt2=0, Cnt4=0, Cnt8=1, and the disabling control signal Bankoff jumps to be at a low level; that is, after the four target refresh commands, the disabling control signal Bankoff generates a falling edge, so as to turn off the refresh indication circuit 11.

If BRC3=1 and BRCDis=BRC2=BRC4=0, the value of N is 4 in this case; the disabling control signal Bankoff jumps to be at a high level when counting to 4 and jumps to be at a low level when counting to 6, so as to turn off the refresh indication circuit 11.

If BRC4=1 and BRCDis=BRC2=BRC3=0, the value of N is 6 in this case; the disabling control signal Bankoff jumps to be at a high level when counting to 4 and jumps to be at a low level when counting to 8, so as to turn off the refresh indication circuit 11.

It should be noted that, as shown in FIG. 7, the generation circuit 12 further includes:
a reset unit 123, configured to generate a two-level reset signal, where the two-level reset signal is used to reset the second-stage counter and the third-stage counter in the counter unit 121.

It should be noted that the reset signal of the first-stage counter in the counter unit 121 is a system-level reset signal RstN (that indicates reset operation at a low level), and the reset signals of the second-stage counter and the third-stage counter are two-level reset signals Rst2N (that indicate reset operation at a low level). The reason for this is that N is generally an even number and the first-stage counter is naturally in a state of 0 after counting, such that an extra reset is not needed and the system-level reset signal RstN is used for resetting only when the system indicates to reset; for the second-stage counter and the third-stage counter, it is necessary to reset not only when the system indicates to reset, but also after each counting is completed, and the reset unit 123 provides the reset logic of the second-stage counter and the third-stage counter.

As shown in FIG. 7, the reset unit 123 includes a ninth NOT gate 412, a NOR gate 414, and a pulse generator 413. The pulse generator 413 receives the first enable signal DRFMIP and generates one pulse by using the level change edge (a falling edge is taken as an example in FIG. 7) of the DRFMIP. As such, when the reset signal RstN is at a low level, the first enable signal DRFMIP enters the falling edge (the output of the target refresh command is completed), or BRCDis=1 (in this case, the second-stage counter and the third-stage counter are not needed), the reset signals Rst2N are at a low level, that is, both the second-stage counter and the third-stage counter are reset.

In summary, the embodiments of the present disclosure provide a memory. The memory can perform the directed refresh operation on a row adjacent to the target memory row that has been activated many times recently, thereby reducing the occurrence probability of a row hammer event and improving data correctness.

In another embodiment of the present disclosure, referring to FIG. 8, a schematic diagram of a composition structure of an electronic device 50 provided according to an embodiment of the present disclosure is shown. As shown in FIG. 8, the electronic device 50 includes at least the aforementioned memory 10.

The above description shows merely preferred embodiments of the present disclosure and is not intended to limit the protection scope of the present disclosure. It should be noted that in the present disclosure, the terms “include”, “comprise”, or any other variants thereof are intended to cover non-exclusive inclusion, such that a process, a method, an item, or an apparatus including a series of elements includes not only those elements but also other elements not explicitly listed, or elements inherent to such process, method, item, or apparatus. Without further limitation, an element defined by the phrase “including a . . . ” does not exclude the presence of additional identical elements in the process, method, item, or apparatus that includes the element. The serial numbers of the embodiments of the present disclosure described above are for the purpose of describing only and do not represent the superiority or inferiority of the embodiments. The methods disclosed in the method embodiments provided in the present disclosure may be combined in any manner without conflict to obtain new method embodiments. The features disclosed in the product embodiments provided in the present disclosure may be combined in any manner without conflict to obtain new product embodiments. The features disclosed in the method or device embodiments provided in the present disclosure may be combined in any manner without conflict to obtain new method or device embodiments. The above description is only the specific embodiments of the present disclosure, but the protection scope of the present disclosure is not limited thereto; changes or substitutions that any one skilled in the art can easily think of within the technical scope disclosed by the present disclosure shall all fall within the protection scope of the present disclosure. Therefore, the protection scope of the present disclosure shall be defined by the protection scope of the claims.

What is claimed is:

1. A memory, comprising:
a refresh indication circuit, configured to receive an external command signal and output a first block selection signal and a first enable signal, wherein when the external command signal indicates a directed refresh operation, the first enable signal is in an enabled state and the first block selection signal indicates a first memory block selected to perform the directed refresh operation; and
a generation circuit, connected to the refresh indication circuit and configured to output N target refresh commands for the first memory block based on a bounded refresh configuration signal and the first block selection signal when the first enable signal is in an enabled state, wherein the bounded refresh configuration signal is used to specify a value of N.

2. The memory according to claim 1, further comprising an address processing circuit, wherein the address processing circuit stores activation information of each memory block; and
the address processing circuit is connected to the generation circuit and is configured to receive the target refresh commands, perform a second verification on a memory block corresponding to the target refresh commands based on the activation information of each memory block, and confirm the second verification as successful if the memory block corresponding to the target refresh commands has been activated in a previous period of time; otherwise, confirm the second verification as failed and perform a preset handling operation if the memory block corresponding to the target refresh commands has not been activated in the previous period of time,
wherein the preset handling operation at least comprises blocking the N target refresh commands.

3. The memory according to claim 2, wherein
the address processing circuit is further configured to, after the second verification succeeds, determine a target memory row in the memory block corresponding to the target refresh commands and perform refresh processing on N rows adjacent to the target memory row by using the N target refresh commands, wherein the target memory row refers to a memory row whose number of activation in the previous period of time meets a preset condition; and
the target memory row is specified by the external command signal or the target memory row is determined by the memory itself.

4. The memory according to claim 2, wherein
the refresh indication circuit is further configured to receive the target refresh commands, perform a first verification on the target refresh commands based on the first block selection signal, output a verification result signal, and transmit the verification result signal to the address processing circuit, wherein if a memory block corresponding to the first block selection signal is consistent with the memory block corresponding to the target refresh commands, the verification result signal characterizes that the first verification succeeds; if the memory block corresponding to the first block selection signal is inconsistent with the memory block corresponding to the target refresh commands, the verification result signal characterizes that the first verification fails; and
the address processing circuit is further configured to receive the verification result signal and, if the verification result signal characterizes that the first verification fails, perform the preset handling operation and no longer perform the second verification; or, if the verification result signal characterizes that the first verification succeeds, continue to perform the second verification.

5. The memory according to claim 2, further comprising:
a sampling control circuit, configured to receive the external command signal and output a second block selection signal if the external command signal indicates execution of a pre-charging operation, wherein the second block selection signal indicates a second memory block selected to perform the pre-charging operation; and
the address processing circuit, connected to the sampling control circuit and further configured to receive the second block selection signal and store activation information of the second memory block based on the second block selection signal.

6. The memory according to claim 5, wherein
the sampling control circuit is configured to decode the external command signal and generate a pre-charge command signal in an enabled state and the second block selection signal if the external command signal characterizes the pre-charging operation; and
the refresh indication circuit is further configured to receive the pre-charge command signal and enter an enabled state based on the pre-charge command signal in the enabled state.

7. The memory according to claim 6, wherein
the refresh indication circuit is further configured to decode the external command signal and output a feedback signal, wherein if the feedback signal indicates the directed refresh operation, the feedback signal has one pulse; if the feedback signal does not indicate the directed refresh operation, the feedback signal keeps a level state unchanged; and
the sampling control circuit, connected to the refresh indication circuit and further configured to receive the feedback signal and adjust the pre-charge command signal to be in a sleep state based on a pulse transition edge of the feedback signal.

8. The memory according to claim 5, wherein when the target memory row is determined by the memory itself, a total number of memory blocks is M, and the address processing circuit comprises M management units, wherein
an i-th management unit among the M management units is configured, after the second block selection signal is received, to perform sampling and latch processing on a gating row address based on the second block selection signal if the second block selection signal indicates that an i-th memory block among the M memory blocks is selected to perform the pre-charging operation, the gating row address indicating a memory row selected to perform an activation operation; and after the address processing circuit confirms the second verification as successful, to determine the target memory row according to at least one latched gating row address.

9. The memory according to claim 7, wherein the sampling control circuit comprises:
a first control unit, configured to receive and decode the external command signal, wherein if a decoded result characterizes a pre-charge command, a pre-charge signal is in an enabled state; if the pre-charge signal is in an enabled state and redundant command bits of the external command signal are at a preset level, an intermediate control signal in an enabled state is output; if the pre-charge signal is in a sleep state or the redundant command bits are not at the preset level, the intermediate control signal in a sleep state is output; and
a second control unit, connected to the first control unit and configured to output the pre-charge command signal in an enabled state when the intermediate control signal in the enabled state is received and adjust the pre-charge command signal to be in a sleep state after the feedback signal is received.

10. The memory according to claim 9, wherein the first control unit comprises:
a latch unit, configured to latch the redundant command bits based on the pre-charge signal and output a first intermediate signal, wherein when the pre-charge signal is in an enabled state and the redundant command bits are at the preset level, the first intermediate signal is in a first preset state;
an enable unit, configured to receive a mode signal and a directed refresh enable signal and output a second intermediate signal, wherein the second intermediate signal is in an enabled state only when the mode signal is in a sleep state and the directed refresh enable signal is in an enabled state; the mode signal in an enabled state characterizes that the memory does not support a directed refresh function, and the directed refresh enable signal in an enabled state characterizes that the directed refresh function is enabled; and
a logic unit, configured to receive the first intermediate signal and the second intermediate signal and output the intermediate control signal in an enabled state only when the first intermediate signal is in the first preset state and the second intermediate signal is in an enabled state.

11. The memory according to claim 10, wherein the enable unit comprises a first NAND gate, a first buffer, a second NAND gate, and a first OR gate, wherein
two input terminals of the first NAND gate respectively receive the mode signal and a system reset inversion signal, an output terminal of the first NAND gate is connected to an input terminal of the first buffer, two input terminals of the first OR gate respectively receive the directed refresh enable signal and a system reset signal, two output terminals of the second NAND gate are respectively connected to the output terminal of the first NAND gate and an output terminal of the first buffer, and one of the output terminals of the second NAND gate outputs the second intermediate signal,
wherein the enabled states of the directed refresh enable signal, the mode signal, and the intermediate control signal all refer to a high level, the enabled state of the second intermediate signal refers to a low level, level states of the system reset inversion signal and the system reset signal are opposite, and the system reset signal at a high level indicates a reset operation.

12. The memory according to claim 9, wherein the second control unit comprises:
a detection unit, configured to receive the feedback signal and output a detection pulse signal, wherein each time the pulse transition edge of the feedback signal is detected, one pulse is generated by the detection pulse signal;
a control unit, connected to the detection unit and configured to receive the intermediate control signal and the detection pulse signal, perform latch processing based on the intermediate control signal and the detection pulse signal, and generate an initial flag signal; and
an output unit, connected to the control unit and configured to perform inverted processing on the initial flag signal and output the pre-charge command signal.

13. The memory according to claim 6, wherein
the generation circuit is further configured to generate a disabling control signal and control the disabling control signal to generate one pulse after the N target refresh commands are output; and
the refresh indication circuit is further configured to receive the disabling control signal and enter a disabled state based on a pulse transition edge of the disabling control signal.

14. The memory according to claim 13, wherein the generation circuit comprises:
a command unit (120), configured to receive the first enable signal and the target refresh commands, generate a count clock signal based on the target refresh commands when the first enable signal is in an enabled state, and control a level state of the count clock signal to keep unchanged when the first enable signal is in a sleep state;
a counter unit, configured to receive the count clock signal, perform counting based on the count clock signal, and generate a command count value; and
a judgment unit, configured to compare the command count value with N and generate the disabling control signal based on a comparison result, wherein if the command count value reaches N, the disabling control signal is controlled to generate one pulse; if the command count value is less than N, the disabling control signal is controlled to keep a level state unchanged.

15. An electronic device, comprising the memory according to claim 1.
